(19) United States
(12) Patent Application Publication
(10) Pub. No.: US 2025/0349540 A1
(43) Pub. Date: Nov. 13, 2025

(54) METALLIZATION STRUCTURE FOR COUPLING BOILING ENHANCED LAYER TO SUBSTRATE IN A COOLING SYSTEM

(71) Applicant: Taiwan Semiconductor Manufacturing Company, Ltd., Hsin-Chu (TW)

(72) Inventor: Chihting Lai, Hsinchu City (TW)

(21) Appl. No.: 19/275,880

(22) Filed: Jul. 21, 2025

Related U.S. Application Data
(63) Continuation of application No. 18/624,906, filed on Apr. 2, 2024.
(60) Provisional application No. 63/617,837, filed on Jan. 5, 2024.

(51) Int. Cl. H01L 21/02; H01L 21/3213; H01L 21/67; H01L 21/768

(52) U.S. Cl. CPC H01L 21/02642; H01L 21/32133; H01L 21/67023; H01L 21/76885

(57) ABSTRACT

A metallization structure is formed over an integrated circuit (IC) substrate from a first side. A patterning process is performed to the metallization structure from the first side. The metallization structure is patterned into a plurality of metallization islands by the patterning process. A plurality of metal-containing structures is formed over the plurality of the metallization islands, respectively, from the first side. A second side of the IC substrate is coupled to an organic substrate. The second side is opposite the first side.

### PRIORITY DATA

This present application is a continuation of U.S. patent application Ser. No. 18/624,906 filed Apr. 2, 2024 “METALLIZATION STRUCTURE FOR COUPLING BOILING ENHANCED LAYER TO SUBSTRATE IN A COOLING SYSTEM”, which claims benefit of provisional U.S. patent application 63/617,837, filed on Jan. 5, 2024, entitled “DIRECT BOILING ENHANCED LAYER FOR TWO-PHASE IMMERSION COOLING”, the disclosure of each of which is hereby incorporated by reference herein in their respective entireties.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

However, as semiconductor fabrication progresses to more advanced technology nodes, additional challenges may arise. For example, IC devices may generate heat during their operations, which should be quickly removed to ensure the proper continued operation of the IC devices. To that end, a direct boiling enhanced layer (BEL) may be attached to IC devices to facilitate the heat removal. However, the BEL is typically attached to the IC devices through a thermal interface material (TIM) and a metallic lid structure, which add additional thermal resistance and therefore may be undesirable. In addition, the implementation of the BEL could lead to excessive IC device warpage, which is also undesirable. Therefore, although existing IC devices and their methods of fabrication have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 illustrates a cooling system according to embodiments of the present disclosure.

FIGS. 2-4 illustrate various cross-sectional side views of an IC structure according to embodiments of the present disclosure.

FIGS. 5-10 illustrate a series of cross-sectional side views of an IC structure at various stages of fabrication according to embodiments of the present disclosure.

FIGS. 11-13 illustrates various planar top views of an IC structure according to embodiments of the present disclosure.

FIG. 14 illustrates an integrated circuit fabrication system according to various aspects of the present disclosure.

FIG. 15 illustrates a flowchart of a method according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to the implementation of a direct boiling enhanced layer (BEL) for 2-phase immersion cooling. In more detail, many of today's computing environments involve IC devices that generate a great amount of heat during operation. For example, a data center that is configured to host computer servers or perform other data intensive operations (e.g., machine learning) may employ hundreds or thousands of Central Processing Units (CPUs) and/or Graphics Processing Units (GPUs) that are constantly running (e.g., executing computing tasks). These CPUs and/or GPUs may generate heat when executing the computing tasks. If not dissipated quickly, such heat may degrade the performance of the CPUs/GPUs (or other IC devices nearby), and/or shorten the lifespan of the CPUs/GPUs, and/or cause premature failures of the CPUs/GPUs.

To ensure the quick removal of the heat generated by IC devices, the IC devices may be placed inside a cooling system that contains a cooling fluid. The cooling fluid may turn into vapor in response to the heat generated by the IC devices. The cooling system may also include a condenser. When the vapor (generated in response to the heat) rises and meets with the condenser, the condenser turns the vapor back into its liquid form, which is recirculated back into the cooling fluid system. Heat generated by the IC devices is thereby removed in this process. A direct boiling enhanced layer (BEL) (which is a metal-containing layer) may be implemented on the IC devices to facilitate the formation/generation of the vapor. However, the implementation of the BEL is often accompanied by a thermal interface material (TIM) and a metallic lid structure. The TIM and the metallic lid structure may be formed between the BEL and a substrate of the IC device and are quite thick. Therefore, the TIM and the metallic structure may introduce additional thermal resistance, which is undesirable.

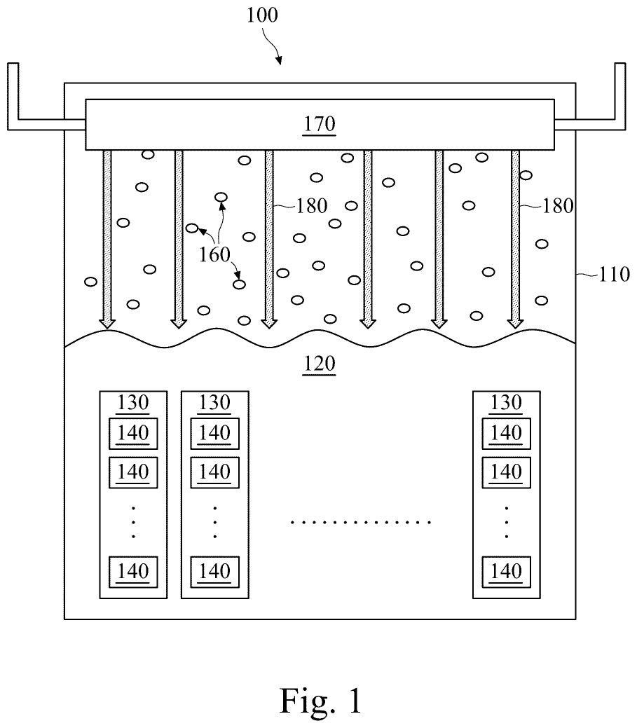

The present disclosure addresses the issues discussed above by forming a BEL-containing structure directly on a substrate of an IC device. By doing so, the TIM and the metallic lid structure may be eliminated, which helps to reduce the overall resistance of the resulting IC device. In addition, the present disclosure may configure the BEL-containing structures as a plurality of discrete islands (separated from one another) to vertically aligned with the locations of thermal hot spot regions. Such an island-like scheme may help to reduce a substrate warpage issue that could otherwise occur. Again, the reduction of substrate warpage may translate into better IC device performance and/or longer lifetime. The various aspects of the present disclosure will now be discussed below in more detail with reference to FIGS. 1-15.

Referring now to FIG. 1, an example 2-phase immersion cooling system 100 is illustrated. The 2-phase immersion cooling system 100 includes an immersion chamber 110, which contains a cooling fluid 120. The cooling fluid 120 may be in liquid form and may have electrically insulative properties. In some embodiments, the cooling fluid 120 may include purified water, which is substantially free of impurities that could otherwise conduct electricity. A plurality of printed circuit boards (PCBs) 130 may be immersed partially, or completely, within the cooling fluid 120. The PCBs 130 may each include a plurality of IC devices 140, such as CPUs, GPUs, or other types of IC chips. During the operation of the IC devices 140—such as when the CPUs and/or GPUs are performing computationally intensive tasks—a great deal of thermal energy in the form of heat may be generated as a result. As discussed above, if such heat is not dissipated quickly, the performance and/or the lifespan of the IC devices 140 may be adversely impacted.

The 2-phase immersion cooling system 100 is configured to dissipate the heat generated by the IC devices 140 quickly and efficiently. For example, the IC devices 140 may each include a BEL, which is a metal-containing material, as discussed further below in greater detail. The BEL facilitates the formation of vapor 160, which is generated based on the cooling fluid 120 in response to the heat produced by the IC devices 140. In other words, the heat produced by the IC devices 140 transforms the cooling fluid 120 near the IC devices 140 from a liquid form into a vapor form (e.g., a phase change for the cooling fluid 120), and the BEL on the IC devices 140 makes it easier and/or quicker for the vapor 160 to form as a result.

The vapor 160 rises upwards within the immersion chamber 110, until the vapor 160 comes into contact with a condenser 170 that is also implemented inside the immersion chamber 110. In some embodiments, the condenser 170 may include a plurality of coils, which may also contain a coolant. When the vapor 160 comes into contact with the condenser 170, the heat within the vapor 160 is absorbed by the condenser 170, which causes the vapor 160 to transform back into a fluid 180 again. The fluid 180 recirculates back down to the cooling fluid 120 (e.g., becomes a part of the cooling fluid 120 again), while the heat transferred to the condenser 170 is released to the outside of the immersion chamber 110. In this manner, the 2-phase immersion cooling system 110 can quickly and efficiently dissipate the heat generated by the IC devices 140 housed therein.

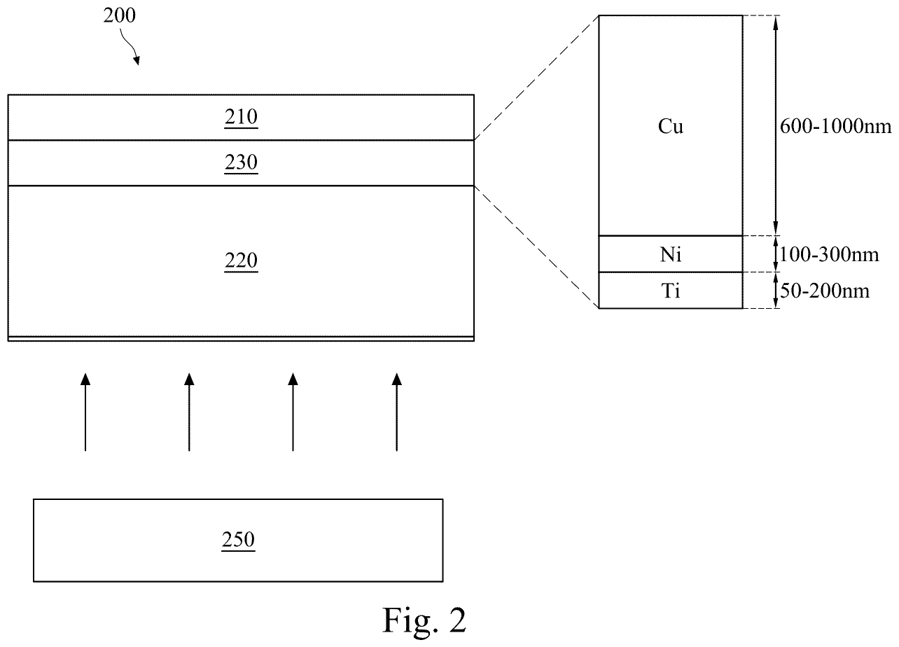

Referring now to FIG. 2, a diagrammatic fragmentary cross-sectional side view of an IC structure 200 on which an example BEL 210 is implemented is illustrated. In more detail, the IC structure 200 includes a substrate 220. In some embodiments, the substrate 220 may be a semiconductor substrate, such as a silicon substrate. In other embodiments, the substrate 220 may include a silicon-on-insulator (Sol) substrate. The substrate 220 may also be referred to as a carrier. In some embodiments, the substrate 220 has a thickness that is in a range between about 500 microns and about 900 microns, for example, between 600 microns and about 800 microns. In some embodiments, the substrate 220 has a thermal conductivity that is in a range between about 100 watts per meter-kelvin (W/mK) and about 140 W/mK. In some embodiments, the substrate 220 has a thermal resistance that is in a range between about 5 millimeter*Celsius per watt (mm²C/W) and about 6.5 mm²C/W.

The IC structure 200 also includes a backside metallization (BSM) 230 disposed over the substrate 220. The BSM 230 may be implemented directly on the surface of the substrate 220. In some embodiments, the BSM 230 serves a role of a seed layer (e.g., an anode) in an electroplating process to be performed subsequently, where the electroplating process may be used to form a BEL structure according to various aspects of the present disclosure. However, in some other embodiments, the BEL structure (to be formed later) may be formed directly on the substrate 220 using a physical vapor deposition (PVD) process or an epitaxy process, and as such, the BSM 230 need not be implemented in those embodiments, as no seed layer would be necessary. In any case, in some embodiments where the BSM 230 is formed, the BSM 230 may include a plurality of metal layers, for example, a titanium (Ti) layer, a nickel (Ni) layer disposed over the Ti layer, and a copper (Cu) layer (which may be a porous structure) disposed over the Ni layer. The Cu layer may serve as a main conductive portion of the BSM 230, the Ti layer may serve as a barrier layer to prevent or at least mitigate the diffusion between the Cu layer and the substrate 220, and the Ni layer may serve as an interface material between the Cu layer and the Ti layer. In such an embodiment, the Ti layer of the BSM 230 may be in direct contact with the surface of the substrate 220. Note that the Ni layer may also serve as a diffusion barrier layer. Other candidate materials (other than Ni) for such a diffusion barrier layer may include MoS₂, TiW, TiN, Ta, or TaN. Also note that the Ti layer may be replaced by other suitable diffusion barrier layer candidates as well, for example, SIN, SiON, SiO₂, SiC, or SiCN.

In some embodiments where the BSM 230 is implemented with the Ti/Ni/Cu configuration, the Cu layer has a thickness in a range between about 600 nanometers (nm) and about 1000 nm, the Ni layer has a thickness in a range between about 100 nm and about 300 nm, and the Ti layer has a thickness in a range between about 50 nm and about 200 nm. In some embodiments, the BSM 230 has a thickness that is in a range between about 0.6 microns and about 1 micron, for example, between 0.7 microns and about 0.9 microns. In some embodiments, the BSM 230 has a thermal conductivity that is in a range between about 300 W/mK and about 500 W/mK. In some embodiments, the BSM 230 has a thermal resistance that is in a range between about 0.001 mm²C/W and about 0.003 mm²C/W. Note that the above configuration of the BSM 230 is not intended to be limiting unless otherwise claimed. For example, in some embodiments, the BSM 230 does not include a copper layer. Instead, the BSM 230 may be implemented using other layers that can serve as an adhesion layer between the substrate 220 and the yet-to-be-formed BEL structure. For example, the BSM 230 may be implemented at least in part using a high conductive adhesive material, such as a silver paste (e.g., silver particles mixed with epoxy) in some embodiments. In such an embodiment, the fabrication process flow may be different. Rather than a deposition->patterning->etching->electroplating process flow (as will be discussed in more detail below), the fabrication process flow may involve singulating the BEL structure (to be formed in a subsequent process) before attaching the BEL structure to the substrate 220.

Returning to the embodiment of FIG. 2, the IC structure 200 implements the BEL 210 directly on the BSM 230 in the illustrated embodiment. Alternatively stated, the BSM 230 is implemented directly between the substrate 220 and the BEL 210. In some embodiments, the BEL 210 and the BSM have different material compositions. Note that the configuration of the IC structure 200 does not require a thermal interface material or a metallic lid structure, which would have been undesirable. In more detail, the BEL 210 is configured to facilitate efficient heat dissipation. For example, when the IC structure 200 is placed in operation, a heat source 250 may be located below the substrate 220 (e.g., on a side opposite the side of the BSM 230). In some embodiments, the heat source 250 may be a device or apparatus external to the IC structure 200 (e.g., heat generated by IC devices external to the IC structure 200). In other embodiments, the heat source 250 may correspond to a region that is internal to the IC structure 200. For example, the heat source 250 may encompass a thermal hot spot region that is located within the substrate 220, where the temperature of the thermal hot spot region is greater than the temperature of the rest of the substrate 220. For example, the substrate 220 may contain various electrical circuits, and some of the electrical circuits (or portions thereof) may generate an excess amount of heat during their operation. As a result, these electrical circuits may raise the temperatures of the regions of the substrate 220 corresponding to these electrical circuits more than the rest of the substrate 220.

Regardless of the details of the heat source 250, the IC structure 200 herein is configured to quickly and efficiently dissipate the heat generated by the heat source 250. One reason for the quick and efficient dissipation of heat is that the material composition of the BEL 210 is specifically configured to achieve such an objective. For example, the BEL 210 may include a metal material and other additives that facilitate the formation of vapor when the IC structure 200 is placed in an environment similar to the 2-phase immersion cooling system 100 discussed above with reference to FIG. 1. That is, when the IC structure 200 is immersed within a fluid similar to the cooling fluid 120 of FIG. 1, the BEL 210 makes it easier for vapor bubbles similar to the vapor 160 of FIG. 1 to form in response to the heat delivered by the heat source 250. The easier formation of the vapor means that the heat can be transferred away from the IC structure 200 (via the vapor) more quickly, which is desirable.

In addition to facilitating the formation of the vapor, the material composition of the BEL 210 is configured to be highly conductive as well. In some embodiments, the BEL 210 includes a metal-containing material. For example, the BEL 210 may include modified metal or ceramic particles with a porous structure. In some embodiments, the BEL 210 may be a metal such as copper, or a ceramic such as AlN. Other candidate materials for the BEL may include silver and/or gold (as a metal other than copper), or SiC and/or diamond (as a ceramic other than AlN). Note that for a ceramic type BEL 210, electroplating may not be feasible, and instead, a singulation followed by an attachment process flow may need to be applied. Regardless of the exact material composition of the BEL 210, the BEL 210 can conduct thermal energy transfer quickly and efficiently. The BEL 210 may also be sufficiently thin, so that its thinness also allows thermal energy to be transferred quickly. For example, in some embodiments, the BEL 210 may have a thickness in a range between about 10 microns and about 200 microns.

Furthermore, the structural configuration of the IC structure 200 further improves the heat dissipation. As discussed above, the IC structure 200 implements the BEL 210 directly on the BSM 230, which itself is implemented directly on the substrate 220. As such, no metallic lid structure or a thermal interface material is needed in the IC structure 200. The thermal interface material, although thinner than the metallic lid structure, may still be much thicker than the BSM 230 of the IC structure 200 herein. In addition, the thermal interface material may have a greater thermal resistivity than the BSM 230. The higher thermal resistivity of the thermal interface material, coupled with the greater thickness, means that the thermal interface material alone may have a greater contribution to overall thermal resistance than the BSM 230 herein. This problem would have been exacerbated by the presence of the metallic lid structure, which is also typically quite thick, which may lead to a relatively high overall thermal resistance as well.

For comparison purposes, an IC structure that utilizes a thermal interface material and a metallic lid structure to couple a BEL to a substrate may have an overall thermal resistance that is in a range between about 25 mm²C/W and about 30 mm²C/W, where a significant majority (e.g., 75%˜85%) of the overall thermal resistance is attributed to the thermal interface material and the metallic lid structure, and only a small amount (e.g., 15%˜25%) of the overall thermal resistance is attributed to the substrate. In contrast, the IC structure 200 herein may have an overall thermal resistance that is in a range between about 5.3 mm²C/W and about 6.3 mm²C/W, where a significant majority (e.g., >99%) of the overall thermal resistance of the IC structure 200 is attributed to substrate 220, and only a small amount (e.g., <1%) of the overall thermal resistance of the IC structure 200 is attributed to the BSM 230 and the BEL 210. Furthermore, the IC structure 200 herein achieves a smaller size (e.g., since the BSM 230 has a substantially smaller thickness compared to the metallic lid structure and the thermal interface material) compared to other IC structures, which is also beneficial.

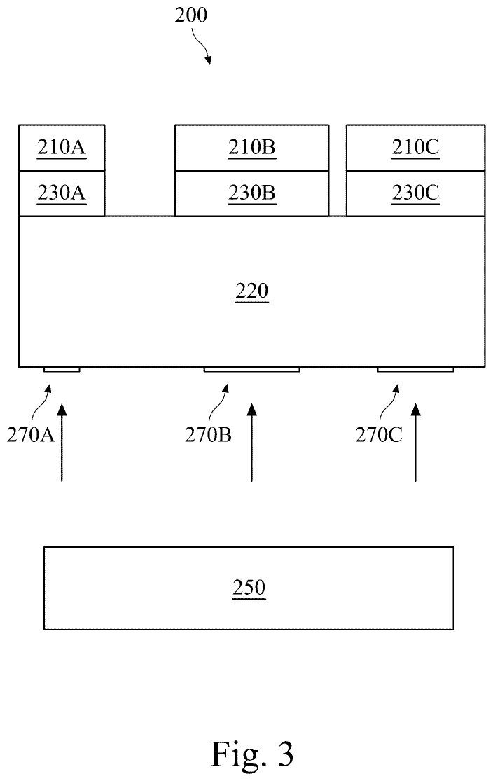

Referring now to FIG. 3, a diagrammatic fragmentary cross-sectional side view of another embodiment of a portion of the structure 200 is illustrated. For reasons of consistency and clarity, similar components are labeled the same. Whereas the BSM 230 and the BEL 210 in the structure 200 in FIG. 2 are each implemented as a continuous structure, the BSM 230A, 230B, and 230C, and the BEL 210A, 210B, and 210C in the IC structure 200 in FIG. 3 are each implemented as a plurality of discrete islands.

FIG. 3 also shows a plurality of thermal hot spot regions 270A, 270B, 270C. As discussed above, a thermal hot spot region may be a region within (or outside) the substrate 220, whose temperature is greater than the temperature of the rest of the substrate 220. In some instances, the temperature difference may be attributed to certain types of electrical circuitry generating more heat than other types of electrical circuitry. Regardless of what caused the thermal hot spot regions 270A, 270B, or 270C, it is desirable to be able to quickly dissipate the heat generated by these hot spot regions, or else the performance and/or the lifespan of the IC structure 200 may be degraded.

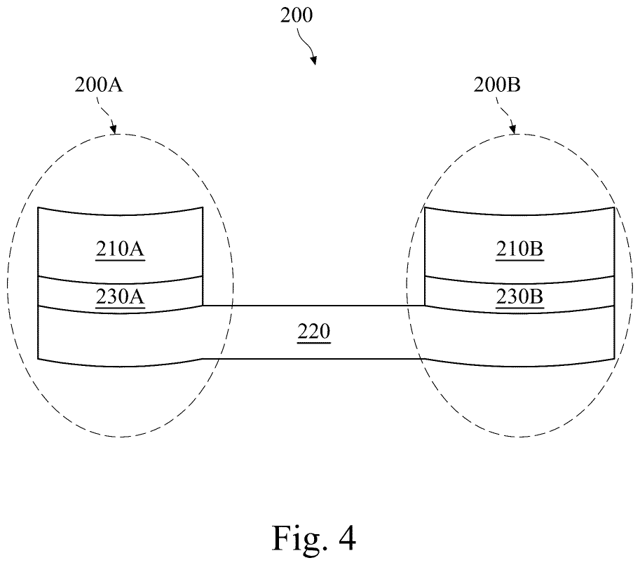

In order to expedite the heat dissipation associated with the thermal hot spot regions 270A, 270B, and 270C, the present disclosure configures the IC structure 200 such that each of the islands 210A/230A, 210B/230B, 210C/230C is vertically aligned with a respective one of the thermal hot spot regions. For example, the BEL island 210A and the BSM island 230A collectively form an island structure that is vertically aligned with the thermal hot spot region 270A, the BEL island 210B and the BSM island 230B collectively form an island structure that is vertically aligned with the thermal hot spot region 270B, and the BEL island 210C and the BSM island 230C collectively form an island structure that is vertically aligned with the thermal hot spot region 270C. Such a configuration of the IC structure helps to prevent (or at least reduce) wafer warpage. Note that in some embodiments, the BEL layers 210A/210B/210C may also be formed on the sidewalls of the BSM layers 230A/230B/230C, respectively. However, this feature may not be specifically illustrated in FIG. 3 (or in FIG. 4 discussed below) for reasons of simplicity.

For example, referring now to FIG. 4, which is another diagrammatic fragmentary cross-sectional side view of an embodiment of a portion of the structure 200. FIG. 4 illustrates a wafer warpage that could occur. For example, due to a mismatch of a coefficient of thermal expansion (CTE) of the material of the substrate 220 and a CTE of the material of the BSM 230 (or the CTE of the BEL 210), the substrate 220 and the BSM 230 (or the BEL 210) may expand and/or contract at different rates, thereby causing a warpage. For example, a portion 200A and/or a portion 200B of the IC structure 200 may experience a curvature. The curvature may be manifested as a concave upper surface of the BEL 210, the BSM 230, and the substrate 220, and/or a convex lower surface of the BEL 210, the BSM 230, and the substrate 220, or vice versa.

Even though the IC structure 200 herein may experience a certain degree of warpage, it is understood that the island structure implementation of the BSM 230 and the BEL 210 can still provide a reduction in the warpage. This is because any warpage in the IC structure 200 is localized. In other words, had the BSM 230 and the BEL 210 not been formed as island structures, but rather over an entirety of the substrate 220, the result would have been a warpage of the substrate 220, the BSM 230, and the BEL 210 in their respective entireties, which would have been far greater. In comparison, the island structures of the BSM 230A/230B and the BEL 210A/210B herein means that any warpage is confined to the localized portions 200A and 200B of the IC structure 200. As such, the overall extent of the warpage or other structural deformations of the IC structure 200 is minimized.

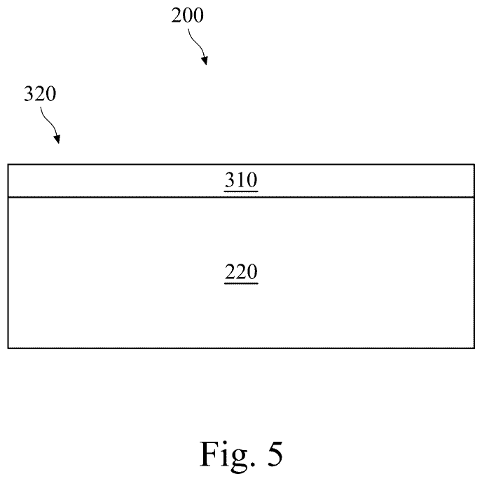

FIGS. 5-10 are a series of diagrammatic fragmentary cross-sectional side views of an embodiment of the IC structure 200 at various stages of fabrication according to various aspects of the present disclosure. For reasons of consistency and clarity, similar elements appearing in FIGS. 5-10 and FIGS. 1-4 will be labeled the same.

Referring to FIG. 5, the IC structure 200 includes the substrate 220. The substrate 220 may comprise an elementary (single element) semiconductor, such as silicon in an embodiment. In other embodiments, the elementary semiconductor of the substrate 220 may include germanium and/or other suitable materials. In some other embodiments, the substrate 220 may include a compound semiconductor, such as silicon carbide, gallium arsenic, gallium phosphide, indium phosphide, indium arsenide, indium antimonide, and/or other suitable materials. In yet other embodiments, the substrate 220 may include an alloy semiconductor, such as SiGe, GaAsP, AlInAs, AlGaAs, GaInAs, GaInP, GaInAsP, and/or other suitable materials. In some embodiments, the substrate 220 may be a single-layer material having a uniform composition. Alternatively, the substrate 220 may include multiple material layers having similar or different compositions suitable for IC device manufacturing. In one example, the substrate 220 may be a silicon-on-insulator (SOI) substrate having a semiconductor silicon layer formed on a silicon oxide layer. In another example, the substrate 220 may include a conductive layer, a semiconductor layer, a dielectric layer, other layers, or combinations thereof.

Various doped regions, such as source/drain regions, may be formed in or on the substrate 220. The doped regions may be doped with n-type dopants, such as phosphorus or arsenic, and/or p-type dopants, such as boron, depending on design requirements. The doped regions may be formed directly on the substrate 220, in a p-well structure, in an n-well structure, in a dual-well structure, or using a raised structure. Doped regions may be formed by implantation of dopant atoms, in-situ doped epitaxial growth, and/or other suitable techniques. The substrate 220 may also include various types of electrical circuitry that are formed at least partially within or on the substrate 220. The electrical circuitry may include planar transistors or three-dimensional transistors such as FinFET devices (where gate structures partially wrap around a fin-like vertically protruding active region) or multi-channel gate-all-around (GAA) devices.

Still referring to FIG. 5, a back end of line (BEOL) structure 310 is formed over a surface of the substrate 220 from a side 320. In some embodiments, the BEOL structure 310 may include a multilayer interconnect (MLI) structure that could provide electrical connectivity to various devices (for example, transistors, resistors, capacitors, and/or inductors) and/or components (for example, gate structures and/or source/drain features) that are formed in or on the substrate 220. For example, the BEOL structure 310 may include a combination of dielectric layers and electrically conductive layers (for example, metal layers, such as nickel, gold, aluminum, etc.) configured to form various interconnect layers. The conductive layers are configured to form vertical interconnect features (providing, for example, vertical connection between features and/or vertical electrical routing), such as contacts and/or vias, and/or horizontal interconnect features (providing, for example, horizontal electrical routing), such as conductive lines. Vertical interconnect features typically connect horizontal interconnect features in different layers (or different planes) of the BEOL structure 310. During operation, the MLI structure of the BEOL structure 310 may route electrical signals between the devices and/or the components of the substrate 220 and/or distribute signals (for example, clock signals, voltage signals, and/or ground signals) to these devices and/or the components. It is understood that regardless of whether the BEOL structure 310 is implemented as including a single interconnect layer in some embodiments or multiple interconnect layers in some other embodiments or, it is illustrated as a single layer structure in FIG. 5 herein for reasons of simplicity.

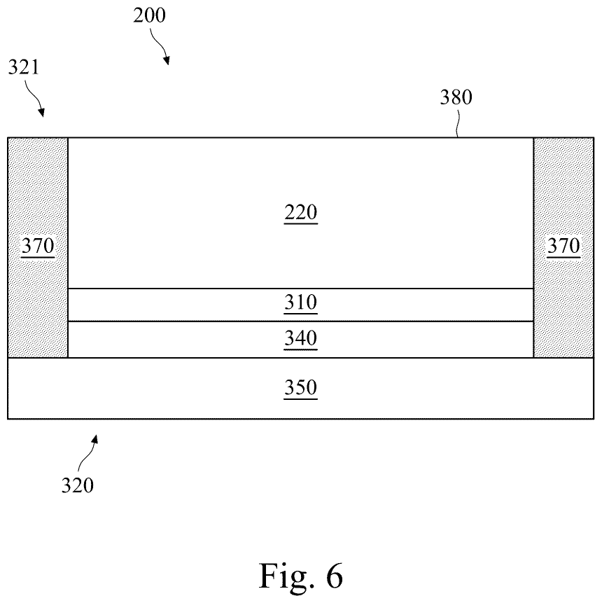

Referring now to FIG. 6, a singulation process may be performed to the IC structure 200 to divide the IC structure 200 into a plurality of smaller IC workpieces. Each IC workpiece of the IC structure 200 may still include a portion of the substrate 220 and a portion of the BEOL structure 310 formed thereon. Each of the IC workpieces of the IC structure 200 is then flipped vertically upside down and bonded to an interposer 350. For example, the side 320 of the BEOL 310 of the IC workpiece is bonded to the interposer 350 through a plurality of micro-bumps 340, which may include a plurality of solder balls or solder bumps in some embodiments. In some embodiments, the interposer 350 includes an electrical interface that facilitates electrical routing. For example, the interposer 350 may include an electrically insulative material and a plurality of conductive vias and/or conductive interconnection features embedded within and/or on the surfaces of the electrically insulative material. Through the conductive vias and/or the conductive interconnection features, electrical access to the electrical circuitries of the IC workpiece (e.g., circuitry within the substrate 220) may be gained externally, for example by connecting to the side 320 of the interposer 350.

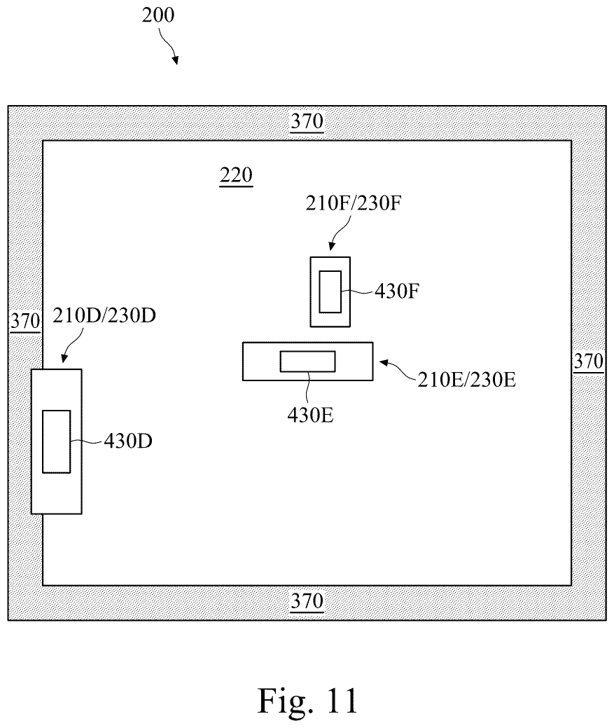

A molding compound 370 is formed over the interposer 350 from a side 321 of the IC structure, where the side 321 is opposite the side 320. The molding compound 370 is also formed on the side surfaces of the substrate 220, the side surfaces of the BEOL 310, and the side surfaces of the micro-bumps 340. It is understood that the molding compound 370 may be formed in a manner that it covers up a surface 380 of the substrate 220. In that case, a grinding process or another suitable molding compound removal process may be performed to partially remove the molding compound 370 from the side 321, until the surface 380 of the substrate 220 is exposed again. The result is that the remaining molding compound 370 may circumferentially surround each of the IC workpieces (e.g., including the substrate 220, the BEOL 310, and the micro-bumps 340) in 360 degrees in a top view, which will be illustrated in FIGS. 11-13 and discussed in more detail below. The molding compound 370 protects the IC workpiece from corrosion, contamination, mechanical deformation, or other undesirable elements.

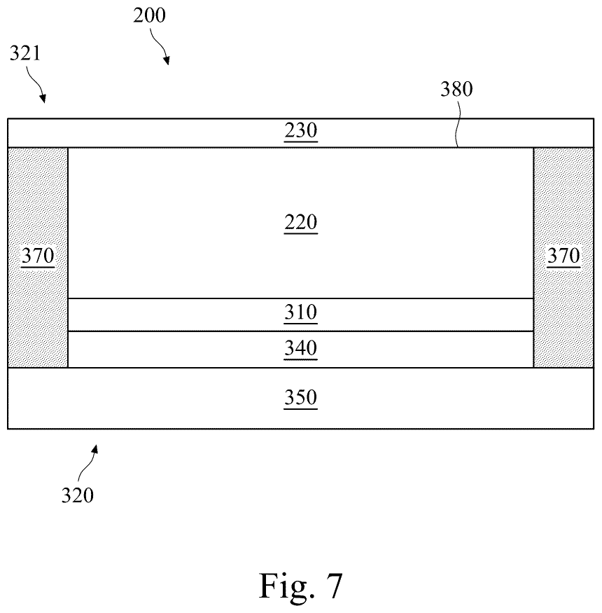

Referring now to FIG. 7, the backside metallization (BSM) 230 is formed directly on the surface 380 of the substrate 220 from the side 321. The BSM 230 is also formed directly on the molding compound 370. As discussed above with reference to FIG. 2, the BSM 230 may include a plurality of conductive sub-layers. For example, the BSM 230 may include a Ti-containing layer (serving as a barrier layer) that is formed directly on the surface 380 of the substrate 220, a Ni-containing layer (serving as an interface layer) that is formed directly on the surface of the Ti-containing layer, and a Cu-containing layer (serving as the main conductive portion of the BSM 230) that is formed directly on the surface of the Ni-containing layer. In some embodiments, the formation of the BSM 230 involves one or more deposition processes. For example, a respective physical vapor deposition (PVD) process or a respective chemical vapor deposition (CVD) process may be performed to form each of the sub-layers of the BSM 230.

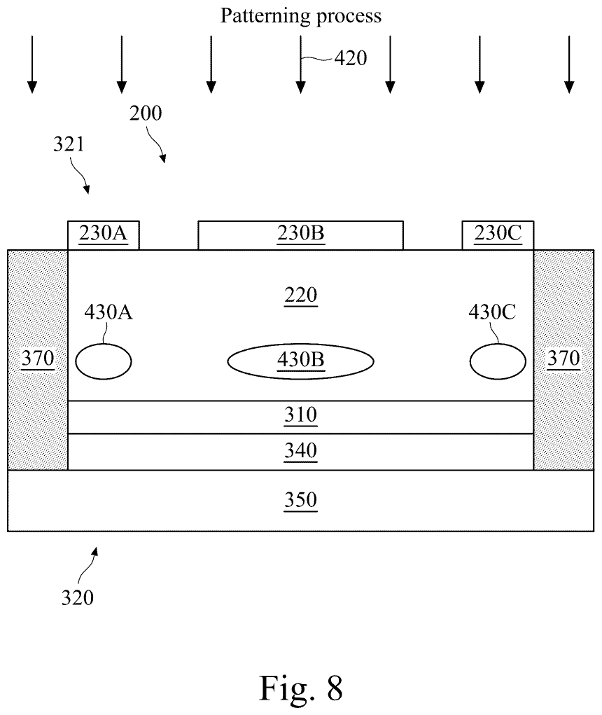

Referring now to FIG. 8, a patterning process 420 is performed to the BSM 230 from the side 321. The patterning process 420 may include a photolithography process, which may include one or more pre-exposure baking processes, exposure processes, post-exposure bake processes, developing processes, etc. As a result of the patterning process 420 being performed, the BSM 230 is transformed into a plurality of BSM islands 230A, 230B, and 230C. The BSM islands 230A, 230B, and 230C are separated from one another in a horizontal direction. As discussed above, the locations of the BSM islands 230A, 230B, and 230C are also configured to be vertically aligned with thermal hot spot regions within the substrate 220 (or even external to the substrate 220), such as thermal hot spot regions 430A, 430B, and 430C, respectively. That is, the BSM island 230A is vertically aligned with the thermal hot spot region 430A, the BSM island 230B is vertically aligned with the thermal hot spot region 430B, and the BSM island 230C is vertically aligned with the thermal hot spot region 430C. Such an alignment scheme means that the heat generated by the thermal hot spot regions 430A, 430B, and 430C can be propagated out of the IC structure 200 through the shortest paths possible (e.g., linear and straight paths). As a result, the heat can be dissipated more quickly and efficiently.

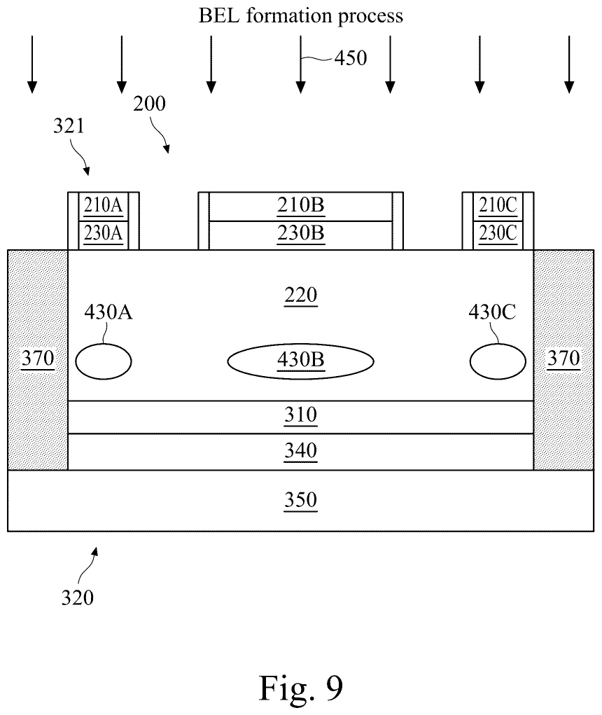

Referring now to FIG. 9, a BEL formation process 450 is performed to the IC structure from the side 321 to form a plurality of BEL islands over the BSM islands 230A/230B/230C, respectively. For example, a BEL island 210A is formed directly on an upper surface and side surfaces of the BSM island 230A, a BEL island 210B is formed directly on an upper surface and side surfaces of the BSM island 230B, and a BEL island 210C is formed directly on an upper surface and side surfaces of the BSM island 230C. In some embodiments, the BEL formation process 450 includes an electroplating process (which may be isotropic), such that the BEL islands 210A, 210B, and 210C are selectively formed directly on the upper and side surfaces of the BSM islands 230A, 230B, and 230C, respectively, but not on the substrate 220 or on the molding compound 370. However, since portions of the side surfaces of the BSM islands 230A/230B/230C are covered by segments of the BEL islands 210A/210B/210C, respectively, it is understood that some small portions of the BEL islands 210A/210B/210C could extend onto the surfaces of the substrate 220 or the molding compound 270. In some other embodiments, a continuous un-patterned BSM layer 230 may be formed, and a continuous un-patterned BEL 210 layer may be formed on the continuous un-patterned BSM layer 230. Thereafter, a patterning process may be performed to define the BSM/BEL islands. In such a process flow, the BEL islands 210A/210B/210C may merely be formed on the upper surfaces of the BSM islands 230A/230B/230C, but not on the side surfaces of the BSM islands 230A/230B/230C.

In some embodiments, the BEL islands 210A, 210B, and 210C have a different material composition than the BSM 230A, 230B, 230C, though they may both contain metal materials. In some embodiments, the BEL islands 210A, 210B, and 210C may include modified copper particles. In some embodiments, the BEL islands 210A, 210B, and 210C may also include a glue and/or a solvent. Regardless of the specific material composition of the BEL islands 210A, 210B, and 210C, it is understood that the BEL islands 210A, 210B, and 210C are configured to facilitate the formation of vapor when the IC structure 200 is placed in an environment such as the system 100 of FIG. 1 discussed above.

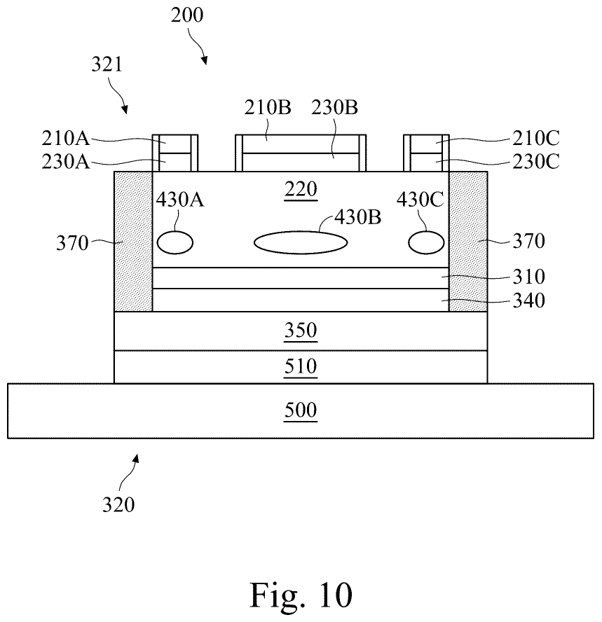

Referring now to FIG. 10, the interposer 350 may be singulated, such that the IC workpieces of the IC structure 200 are separated from one another (though with a respective portion of the interposer 350 attached thereon). Each of the IC workpieces may then be attached to an organic substrate 500 through a plurality of bumps 510. For example, the bumps 510 may include electrically and thermally conductive materials, such as solder balls, that are deposited onto the side 321 of the organic substrate 500. The interposer 350 of the IC workpiece may then be bonded to the organic substrate 500 through the bumps 510, for example, via a flip chip method. It is understood that the IC workpiece, along with the organic substrate, may also be attached to a PCB, such as the PCB 130 of FIG. 1. However, for reasons of simplicity, the PCB is not illustrated in FIG. 10.

Referring now to FIGS. 11-13, diagrammatic fragmentary top views of various embodiments of the IC structure 200 is illustrated. Referring to FIG. 11, the IC structure 200 includes a plurality of discrete island structures that are aligned with a plurality of thermal hot spot regions 430D, 430E, and 430F. For example, an island structure that is aligned with the thermal hot spot region 430D includes a BEL island 210D and a BSM island 230D, another island structure that is aligned with the thermal hot spot region 430E includes a BEL island 210E and a BSM island 230E, and yet another island structure that is aligned with the thermal hot spot region 430F includes a BEL island 210F and a BSM island 230F. Note that the alignment between the thermal hot spot regions and their corresponding BEL/BSM island structures is manifested as an overlap between them in the top view. In addition, to improve the heat dissipation, the size (e.g., area) of the island structures are greater than their corresponding thermal hot spot regions. In some embodiments, the area of island structure made up of the BEL 210D and the BSM 230D may be at least twice as big as the area of the corresponding thermal hot spot region 430D. For example, the thermal hot spot region 430D may be completely covered by the island structure made up of the BEL 210D and the BSM 230D in the top view. It is also understood that although the shapes of the BEL islands and BSM islands are illustrated as rectangles herein, other top view shapes may also be implemented for them, such as circles, diamonds, triangles, or any other suitable arbitrary shape.

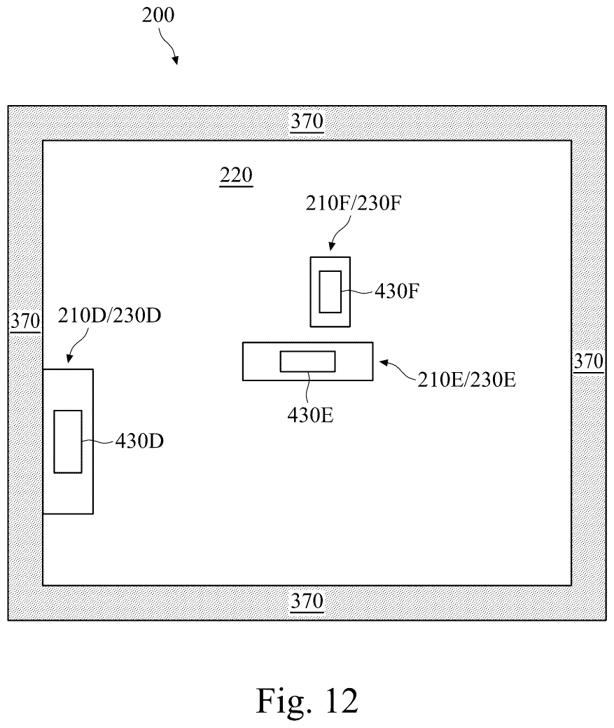

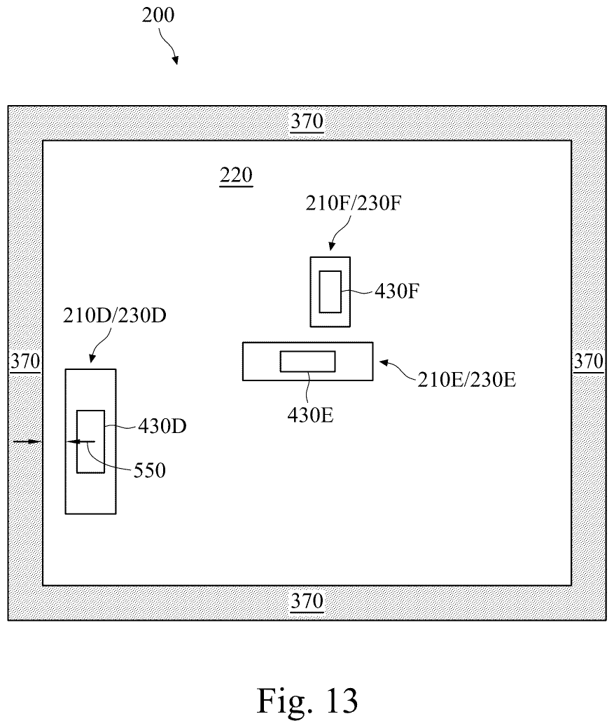

FIG. 11 also illustrates the molding compound 370, which may encircle all four sides (e.g., in 360 degrees) of the IC structure 200, including the thermal hot spot regions 430D, 430E, and 430F, as well as the corresponding island structures aligned with the thermal hot spot regions. In the embodiment of FIG. 11, the molding compound 370 may also be overlapping with one of the island structures (e.g., the island structure made up of the BEL 210D and the BSM 230D) in the top view. This may be due to the location of the thermal hot spot region 430D being very close to the molding compound 370. However, this is not necessarily the case in other embodiments. For example, in the embodiment shown in FIG. 12, the molding compound 370 does not overlap with the island structure made up of the BEL 210D and the BSM 230D in the top view. Instead, the inner boundary of the molding compound 370 may form an interface with an outer boundary of the island structure made up of the BEL 210D and the BSM 230D in the top view. As another example, in the embodiment shown in FIG. 13, not only is there no overlap between the molding compound 370 and the island structure made up of the BEL 210D and the BSM 230D, but a gap 550 may exist between the island structure and the molding compound 370. Again, the location(s) of the island structure(s) may be flexibly configured based on the location(s) of the thermal hot spot region(s).

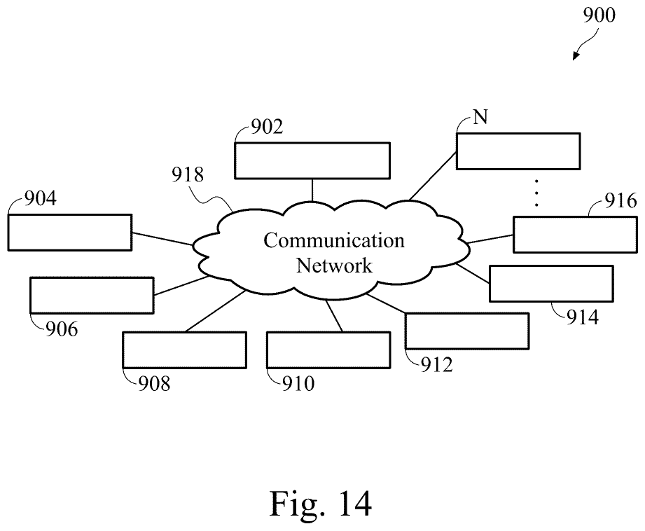

FIG. 14 illustrates an integrated circuit fabrication system 900 according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such the processing tools to perform the various deposition processes discussed above; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

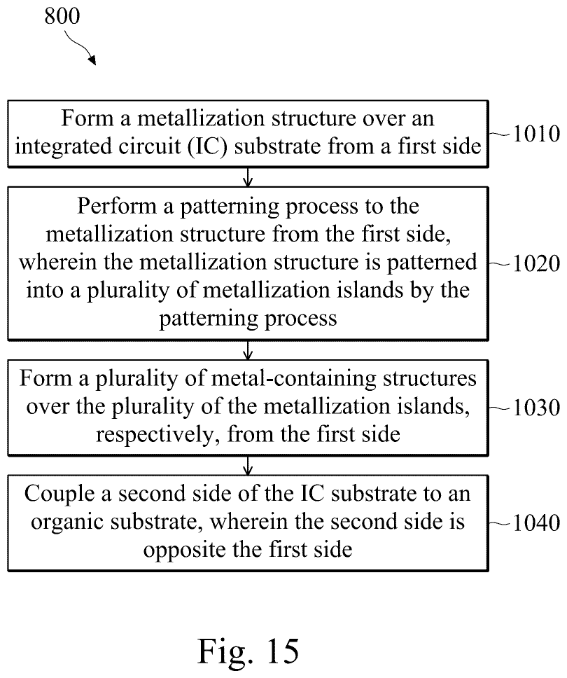

FIG. 15 is a flowchart illustrating a method 1000 according to an embodiment of the present disclosure. The method 1000 includes a step 1010 to form a metallization structure over an integrated circuit (IC) substrate from a first side.

The method 1000 includes a step 1020 to perform a patterning process to the metallization structure from the first side. The metallization structure is patterned into a plurality of metallization islands by the patterning process.

The method 1000 includes a step 1030 to form a plurality of metal-containing structures over the plurality of the metallization islands, respectively, from the first side.

The method 1000 includes a step 1040 to couple a second side of the IC substrate to an organic substrate. The second side is opposite the first side.

In some embodiments, the substrate includes a plurality of thermal hot spot regions. In some embodiments, the patterning process is performed such that each of the metallization islands is aligned with a respective one of the thermal hot spot regions. In some embodiments, in a top view, an area of each of the metallization islands is larger than an area of the thermal hot spot region aligned therewith.

In some embodiments, the forming of the plurality of metal-containing structures is performed such that the plurality of metal-containing structures are selectively formed on surfaces of the metallization islands but not on a surface of the IC substrate.

In some embodiments, the forming of the plurality of metal-containing structures comprises an electroplating process.

In some embodiments, the forming the metallization structure comprises: forming a titanium-containing layer as a first sub-layer of the metallization structure over the first side of the substrate; forming a nickel-containing layer as a second sub-layer of the metallization structure over the titanium-containing layer; and forming a copper-containing layer as a third sub-layer of the metallization structure over the nickel-containing layer.

In some embodiments, the metallization structure and the metal-containing structures have different material compositions.

It is understood that additional processes may be performed before, during, or after the steps 1010-1040 of the method 1000. For example, the method 1000 may include a step of performing a cooling process in which the IC substrate is submerged in a cooling fluid. Heat generated by the IC substrate is dissipated by a vapor formed from the cooling fluid. The metal-containing structures facilitate a formation of the vapor. As another example, the method 1000 may further include the following steps performed before the forming the metallization structure: singulating a wafer containing the IC substrate into a plurality of IC devices; after the singulating, coupling the second side of the IC substrate of each of the IC devices to an interposer; forming a molding compound structure over the first side of the interposer and over the first side of the IC substrate of each of the IC devices; and grinding the molding compound from the first side until a surface of the IC substrate of each of the IC devices is exposed to the first side. In some embodiments, the metallization structure is formed over the first side of the molding compound structure and over the surface of the IC substrate. In some embodiments, at least a subset of the metal-containing structures is formed to be vertically overlapping with the molding compound structure. For reasons of simplicity, other additional steps are not discussed herein in detail.

In summary, the present disclosure involves coupling a BEL to an IC structure through a BSM, such that the BSM (which may include a plurality of metal-containing sub-layers) is located directly between the BEL and the substrate of the IC structure. The BEL and the BSM are also configured as a plurality of discrete island structures that are aligned with a plurality of thermal hot spot regions, respectively. By doing so, the present disclosure offers advantages over other IC structures. It is understood, however, that other embodiments may offer additional advantages, and not all advantages are necessarily disclosed herein, and that no particular advantage is required for all embodiments. One advantage is improved device performance. In more detail, the BEL is formed to facilitate the formation of vapor in a 2-phase cooling system discussed above with reference to FIG. 1, which can help quickly dissipate the heat generated by the IC structures. However, some IC structures may require a thermal interface material and a metallic lid structure to couple the BEL to the substrate of the IC structure. The thermal interface material and the metallic lid structure may be thick and/or have high thermal resistivity, which may unduly add to the overall thermal resistance of the IC structure. In contrast, the direct implementation of the BEL on the substrate via the BSM means that the thermal interface material and the metallic lid structure are no longer necessary. The BSM herein is much thinner and have a lower thermal resistivity than the thermal interface material and the metallic lid structure. As a result, the IC structure may have a lower overall thermal resistance, which leads to faster cooling.

The alignment scheme between the thermal hot spot regions and the BEL/BSM island structures also promotes better heat dissipation. In more detail, the IC structure may include one or more IC dies that contain electrical circuitries, where the heat generated by some of the electrical circuitries may result in thermal hot spot regions having elevated temperatures compared to a rest of the IC structure. If the heat is not quickly dissipated, it may lead to device performance degradations and/or shortened lifespan of the IC structure. Here, the islands (made up of the BSM and the BEL) may be vertically aligned with the thermal hot spot regions. In this manner, a short path between the thermal hot spot regions and the island structure may be established, and the heat may be quickly dissipated. As a result, the IC structure may operate in a cooler environment overall, which improves device performance (e.g., faster speed or lower power consumption). Another advantage is a longer lifespan of the IC structure. In that regard, when an IC structure operates in an environment with elevated temperatures for an extended period of time, it may have a reduced lifespan. Here, the quick and efficient thermal dissipation (made possible by the implementation of the BSM/BEL island structures to align with the thermal hot spot regions) may help prevent, or at least reduce, the operation of the IC structure in an elevated temperature environment. Accordingly, the lifespan of the IC structure of the present disclosure may be prolonged. Other advantages include compatibility with existing fabrication and/or packaging processes, so the present disclosure does not require additional processing and is therefore easy and cheap to implement.

One aspect of the present disclosure pertains to a method. A metallization structure is formed over an integrated circuit (IC) substrate from a first side. A patterning process is performed to the metallization structure from the first side. The metallization structure is patterned into a plurality of metallization islands by the patterning process. A plurality of metal-containing structures is formed over the plurality of the metallization islands, respectively, from the first side. A second side of the IC substrate is coupled to an organic substrate. The second side is opposite the first side.

Another aspect of the present disclosure pertains to a device. The device includes a substrate containing electrical circuitry. The device includes a plurality of metallization structures disposed directly on the substrate in a cross-sectional side view. The device includes a plurality of metal-containing structures disposed directly on the plurality of the metallization structures, respectively, in the cross-sectional side view. The metallization structures and the metal-containing structures have different material compositions. The electrical circuitry includes a plurality of thermal hot spot regions distributed in different locations of the substrate. Each of the metal-containing structures is vertically aligned with a respective one of the thermal hot spot regions in the cross-sectional side view.

Yet another aspect of the present disclosure pertains to a system. The system includes a chamber. The system includes a cooling fluid partially filling the chamber. The system includes a condenser. The system includes a plurality of printed circuit boards (PCBs) submerged within the cooling fluid. The system includes a plurality of integrated circuit (IC) devices located on each of the PCBs. Each of the IC devices includes a substrate, a plurality of metallization islands disposed directly on the substrate, and a plurality of metal-containing islands disposed directly on the metallization islands, respectively. The metallization islands promote a transformation of the cooling fluid into vapor in response to heat generated by the IC devices. The vapor, upon coming into contact with the condenser, transforms back into the cooling fluid.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A structure, comprising:
a substrate that contains a first region that is capable of producing heat;
an interconnect structure disposed over a first side of the substrate in a cross-sectional side view;
a first metallization component disposed over a second side of the substrate in the cross-sectional side view, wherein the second side is opposite the first side; and
a first boiling enhanced layer (BEL) disposed over a top surface and side surfaces of the first metallization component in the cross-sectional side view, wherein a location of the first region coincides with a location of the first metallization component and a location of the first BEL in a planar top view.

2. The structure of claim 1, wherein the first region contains electrical circuitry that, when in operation, has a greater temperature than a rest of the substrate.

3. The structure of claim 1, wherein the first region is circumferentially surrounded by the first BEL in the planar top view.

4. The structure of claim 1, wherein:
the first metallization component has a first material composition; and
the first BEL has a second material composition different from the first material composition.

5. The structure of claim 4, wherein:
the first metallization component contains titanium, nickel, and copper; and
the first BEL contains particles with a porous structure.

6. The structure of claim 1, wherein:
the substrate further comprises a second region that is capable of producing heat, the second region being spaced apart from the first region;
the structure further comprises a second metallization component disposed over the second side of the substrate and a second BEL disposed over a top surface and side surfaces of the second metallization component in the cross-sectional side view; and
a location of the second region coincides with a location of the second metallization component and a location of the second BEL in the planar top view.

7. The structure of claim 1, further comprising an organic substrate that is coupled to the interconnect structure from the second side in the cross-sectional side view.

8. The structure of claim 7, further comprising a plurality of conductive bumps and an interposer layer disposed between the interconnect structure and the organic substrate in the cross-sectional side view.

9. The structure of claim 1, further comprising a molding compound that circumferentially surrounds the substrate in the planar top view, wherein the molding compound extends to side surfaces of the substrate and side surfaces of the interconnect structure in the cross-sectional side view.

10. The structure of claim 9, wherein the molding compound overlaps with a nearest side surface of the first BEL in the planar top view.

11. The structure of claim 9, wherein the molding compound is spaced apart from a nearest side surface of the first BEL in the planar top view.

12. A structure, comprising:
a substrate that contains a first thermal hotspot region and a second thermal hotspot region spaced apart from the first thermal hotspot region, wherein the first thermal hotspot region and the second thermal hotspot region contain electrical circuitry that, when operated, causes the first thermal hotspot region and the second thermal hotspot region to have elevated temperatures compared to a rest of the substrate;
an interconnect structure disposed over a front side of the substrate in a cross-sectional side view;
a first metallization component and a second metallization component disposed over a back side of the substrate in the cross-sectional side view; and
a first boiling enhanced layer (BEL) component and a second BEL component disposed over a top surface and side surfaces of the first metallization component and the second metallization component, respectively, in the cross-sectional side view, wherein the first thermal hotspot region at least partially overlaps with the first BEL component in a planar top view, and the second thermal hotspot region at least partially overlaps with the second BEL component in the planar top view.

13. The structure of claim 12, wherein:
the first thermal hotspot region is circumferentially surrounded by the first BEL component in the planar top view; and
the second thermal hotspot region is circumferentially surrounded by the second BEL component in the planar top view.

14. The structure of claim 12, wherein:
the first metallization component and the second metallization component each contain titanium, nickel, and copper; and
the first BEL component and the second BEL component each contain ceramic particles with a porous structure.

15. The structure of claim 12, further comprising:
a molding compound that circumferentially surrounds the substrate in the planar top view, wherein the molding compound extends to side surfaces of the substrate and side surfaces of the interconnect structure in the cross-sectional side view; and
an organic substrate that is coupled to the interconnect structure from the front side in the cross-sectional side view.

16. A system, comprising:
a chamber that contains a cooling fluid;
a condenser disposed within the chamber; and
an integrated circuit (IC) device disposed within the cooling fluid, wherein the IC includes:
a substrate that contains a heat-generating region;
an interconnect structure disposed over a first side of the substrate in a cross-sectional side view;
a metallization component disposed over a second side of the substrate opposite the first side in the cross-sectional side view; and
a boiling enhanced layer (BEL) component disposed over the metallization component in the cross-sectional side view, wherein a location of the heat-generating region overlaps with a location of the BEL component in a planar top view, wherein heat generated by the heat-generating region transforms the cooling fluid into vapor, and wherein the condenser transforms the vapor back into the cooling fluid.

17. The system of claim 16, wherein the IC device is implemented on a printed circuit board (PCB) that is submerged within the cooling fluid.

18. The system of claim 17, wherein:
the PCB includes a plurality of Graphics Processing Units (GPUs) or a plurality of Central Processing Units (CPUs); and
each of the GPUs or each of the CPUs is implemented as an instance of the IC device.

19. The system of claim 16, wherein a portion of the substrate is in direct contact with a portion of the BEL component.

20. The system of claim 16, wherein:
the metallization component contains titanium, nickel, and copper; and
the BEL component contains ceramic particles with a porous structure.
